(19) United States
(12) Patent Application Publication
(10) Pub. No.: US 2006/0163694 A1
(43) Pub. Date: Jul. 27, 2006

(54) Semiconductor device having spiral-shaped inductor

(75) Inventor: Tatsuya Ohguro, Yokohama-shi (JP)

Correspondence Address: FOLEY AND LARDNER LLP;SUITE 500, 3000 K STREET NW, WASHINGTON, DC, 20007, US

(73) Assignee: KABUSHIKI KAISHA TOSHIBA

(21) Appl. No.: 11/315,598

(22) Filed: Dec. 23, 2005

(30) Foreign Application Priority Data
Dec. 27, 2004 (JP) 2004-376601

(51) Int. Cl. H01L 29/00

(52) U.S. Cl. 257/531

(57) ABSTRACT

An element isolation region is formed in a surface region of a semiconductor substrate. A spiral-shaped inductor is formed above the element isolation region. A conductive region to which a constant potential is applied is formed inside the inner circumference of the inductor.

### CROSS-REFERENCE TO RELATED APPLICATIONS

This application is based upon and claims the benefit of priority from prior Japanese Patent Application No. 2004-376601, filed Dec. 27, 2004, the entire contents of which are incorporated herein by reference.

### BACKGROUND OF THE INVENTION

1. Field of the Invention

The present invention relates to a semiconductor device having an inductor element formed on, for example, a semiconductor substrate.

2. Description of the Related Art

In recent years, the progress of a system-on-chip (SoC) has been significant in achieving a high-performance semiconductor chip. For example, a semiconductor chip for a wireless communication system including a high-frequency circuit such as a wireless local area network (LAN) requires an inductor. This inductor is formed on the semiconductor chip to realize reductions in area and cost of the chip.

Such an on-chip inductor is formed by, for example, a metal wire having a spiral shape on a semiconductor substrate. When a high-frequency current flows in the inductor, a high-frequency current also flows in the semiconductor substrate as a result of coupling. The current flowing in the substrate affects other circuits in the foam of noise. The current flowing in the substrate also affects the performance of the inductor, decreasing the quality (Q) factor of the inductor.

Conventionally, in order to solve this problem, the following technique has been developed. That is, a guard ring is formed outside the outer periphery of the spiral-shaped inductor, and ground potential is applied to the guard ring to stabilize the substrate potential and so improve the Q-factor of the inductor. However, the inductor occupies an area on the substrate larger than that of another circuit. For this reason, when a guard ring for the inductor is formed outside the inductor, the area occupied by the inductor is further increased. Furthermore, a change in magnetic flux generated by the inductor generates an induced electromotive force in the guard ring. An induced current flows in the guard ring depending on the induced electromotive force, and the induced current changes the inductance of the inductor. In addition, the induced electromotive force generated in the guard ring causes an energy loss in the inductor, thereby degrading the Q-factor of the inductor.

As a related technique, a technique that forms a shield layer between an inductor and a substrate has been developed (see, for example, U.S. Pat. No. 6,437,409). According to this technique, an eddy current in a substrate is suppressed by a shield layer having a plurality of slits formed therearound to reduce noise in the substrate, thereby preventing the Q-factor from being degrade.

Therefore, a semiconductor device that can reduce the area occupied by an inductor on a substrate and can improve the performance of the inductor is demanded.

### BRIEF SUMMARY OF THE INVENTION

According to an aspect of the invention, there is provided a semiconductor device comprising: a semiconductor substrate; an element isolation region formed in a surface region of the semiconductor substrate; a spiral-shaped inductor formed above the element isolation region; and a conductive region which is formed inside an inner circumference of the inductor and to which a constant potential is applied.

According to another aspect of the invention, there is provided a system LSI comprising: a semiconductor substrate; and a circuit including a spiral-shaped inductor formed in the semiconductor substrate, the inductor comprising: an element isolation region formed in a surface region of the semiconductor substrate; a spiral-shaped conductive layer formed above the element isolation region; and a conductive region formed inside which is formed inside an inner circumference of the spiral-shaped conductive layer and to which a constant potential is applied.

### BRIEF DESCRIPTION OF THE SEVERAL VIEWS OF THE DRAWING

FIG. 1 is a plan view showing a first embodiment of the invention;

FIG. 2 is a sectional view along a line II-II in FIG. 1;

FIG. 3 is a sectional view showing a manufacturing step in FIG. 2;

FIG. 4 is a sectional view showing a manufacturing step subsequent to the step in FIG. 3;

FIG. 5 is a sectional view showing a manufacturing step subsequent to the step in FIG. 4;

FIG. 6 is a graph showing Q-factors of inductors in the prior art and the first embodiment in comparison with each other;

FIG. 7 is a graph showing inductances of the inductors in the prior art and the first embodiment in comparison with each other;

FIG. 8 is a sectional view showing a second embodiment of the invention;

FIG. 9 is a sectional view showing a third embodiment in which a configuration of the third embodiment is applied to the configuration of the first embodiment;

FIG. 10 is a sectional view showing the third embodiment in which the configuration of the third embodiment is applied to the configuration of the second embodiment;

FIGS. 11A to 11C are plan views showing a fourth embodiment of the invention;

FIG. 12 is a plan view showing the fourth embodiment; and

FIG. 13 is a plan view showing an example of a semiconductor device to which the present invention is applied.

### DETAILED DESCRIPTION OF THE INVENTION

Embodiments of the present invention will be described below with reference to the accompanying drawings.

### First embodiment

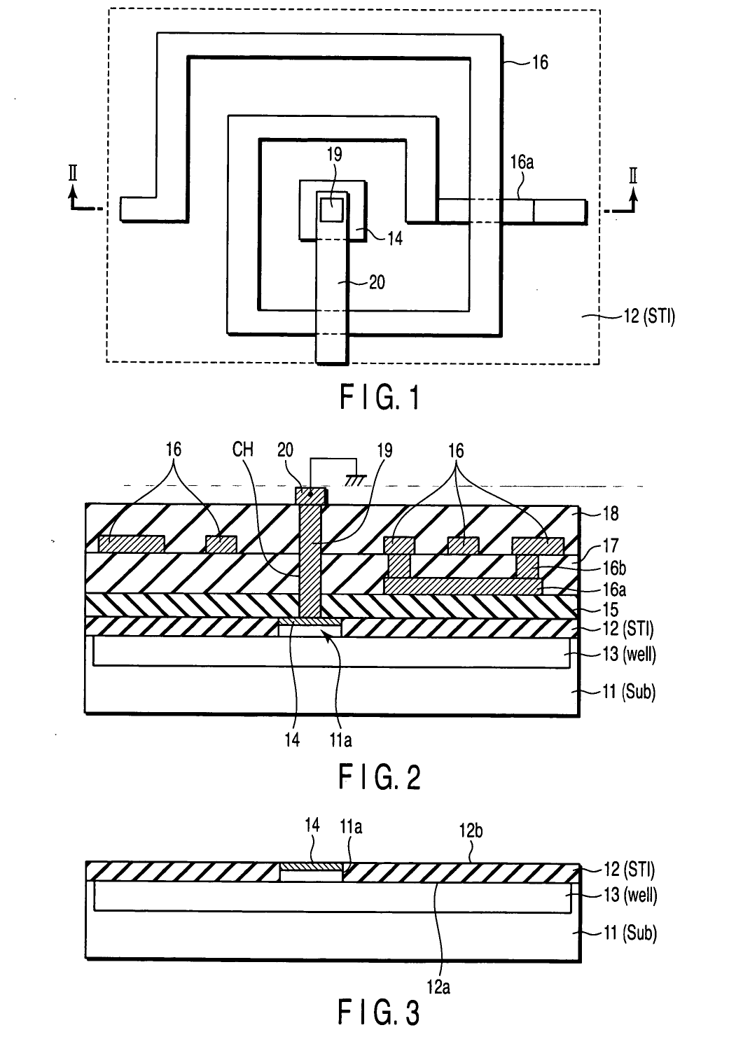

FIGS. 1 and 2 show a first embodiment of the invention. An element isolation region 12 is formed in a surface region of a semiconductor substrate 11. The element isolation region 12 is formed by, for example, shallow trench isolation (STI). The element isolation region 12 exposes the substrate 11 at a position corresponding to, for example, a central portion inside the internal circle of an inductor to be described later. A well region 13 is formed in the substrate 11 covered with the element isolation region 12. The well region 13 is formed in accordance with a region in which the inductor is to be formed. A silicide layer 14 is formed on a surface of a substrate serving as a conductive region 11a exposed from the element isolation region 12. Interlayer insulating films 15 and 17 are formed on the element isolation region 12 and the silicide layer 14.

A spiral-shaped inductor 16 is formed on the interlayer insulating films 15 and 17. A crossing portion 16a and contacts 16b and 16c of the inductor 16 are formed in the interlayer insulating film 17. The inductor 16 is covered with an insulating film 18. An opening CH which exposes the silicide layer 14 is formed in the insulating films 18, 17, and 15. A contact 19 connected to the silicide layer 14 is formed in the opening CH. A wiring 20 formed on the insulating film 18 is connected to the contact 19. A constant potential, for example, ground potential is applied to the wiring 20. For this reason, ground potential is applied to the well region 13 through the contact 19, the silicide layer 14, and the conductive region 11a. The potential is not limited to ground potential, and a potential depending on the characteristics of the semiconductor device may be applied.

FIGS. 3 to 5 show a manufacturing method according to the first embodiment. As shown in FIG. 3, a trench 12a is formed in the surface region of the semiconductor substrate 11 in accordance with an inductor forming region. In this manner, substrate is left like an island at almost the center of the trench 12a to form the conductive region 11a. Thereafter, an insulating film 12b is formed on the entire surface of the substrate 11. The insulating film 12b is planarized by, for example, the chemical mechanical polishing (CMP) method to form the element isolation region 12. Subsequently, for example, boron is ion-implanted in the substrate 11 in accordance with a region in which the inductance is to be formed to form the well region 13. High-concentration p-type impurity ions are implanted to activate the well region 13. Thereafter, the surface of the conductive region 11a exposed from the element isolation region 12 is silicified to form the silicide layer 14.

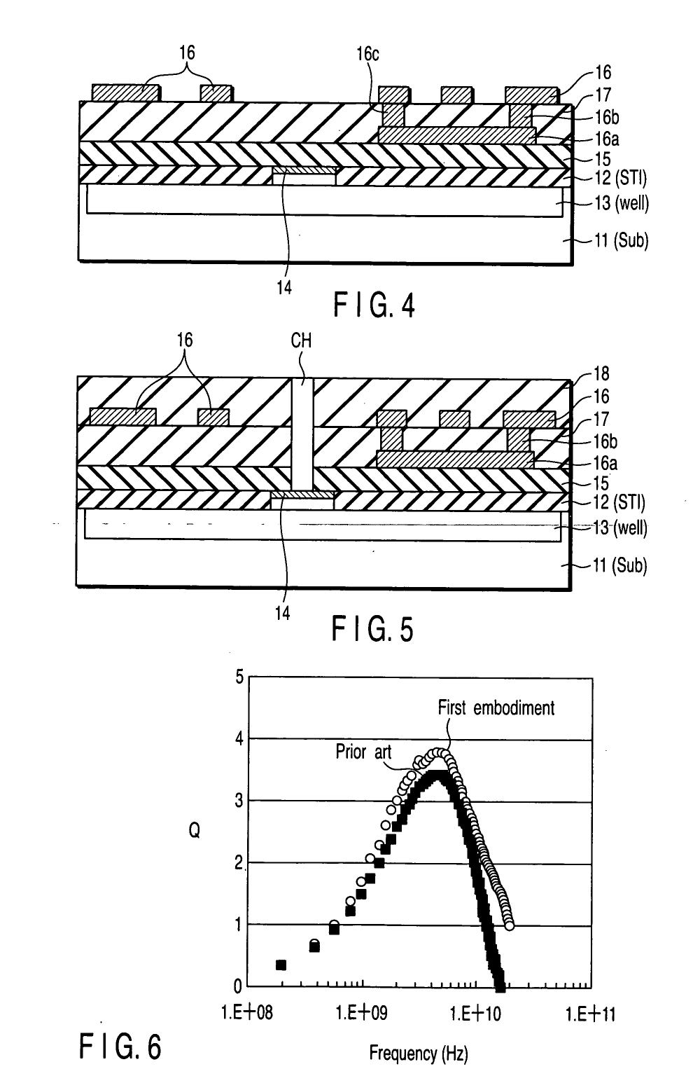

Next, as shown in FIG. 4, the interlayer insulating film 15 is formed on the element isolation region 12 and the silicide layer 14. The crossing portion 16a of the spiral-shaped inductor 16 is formed on the interlayer insulating film 15. Thereafter, the interlayer insulating film 17 is formed on the entire surface of the resultant structure. The contacts 16b and 16c connected to both ends of the crossing portion 16a in the interlayer insulating film 17 are formed. Furthermore, the spiral-shaped inductor 16 is formed on the interlayer insulating film 17.

As shown in FIG. 5, the insulating film 18 is formed on the entire surface of the resultant structure, and the opening CH which exposes the silicide layer 14 is formed in the insulating film 18 and the interlayer insulating films 17 and 15. A metal such as tungsten is buried in the opening CH to form a contact 19 as shown in FIGS. 1 and 2. Thereafter, the wiring 20 connected to the contact 19 is formed on the insulating film 18.

According to the first embodiment, the conductive region 11a and the contact 19 connected to the well region 13 of the substrate 11 are formed on a central portion inside the inner circle of the spiral-shaped inductor 16 to apply a constant potential to the well region 13 through the conductive region 11a and the contact 19. For this reason, even though a magnetic field is generated by the inductor 16, the potential of the substrate 11 can be stably maintained.

Unlike in the prior art, a guard ring larger than the outer circumference of the inductor is not necessary. For this reason, the inductor can be prevented from being increased in size.

Furthermore, a large guard ring is not necessary, and an induced electromotive force is generated in only a small region of the contact 19 and conductive region 11a. For this reason, as in the prior art, the energy loss of the inductor caused by the guard ring can be reduced. Therefore, the Q-factor of the inductor can be increased. That is, in order to increase the Q-factor, the induced electromotive force generated according to the magnetic field of the inductor must be reduced. As in the prior art, when a large guard ring is formed, a large induced electromotive force is generated in the guard ring to cause an induced current to flow. For this reason, energy loss of the inductor increases, thereby decreasing the Q-factor. In contrast to this, in the first embodiment, since an induced electromotive force generated according to the magnetic field of the inductor 16 is generated in the portions corresponding to the conductive region 11a and the contact 19, the induced electromotive force can be reduced. Therefore, the energy loss of the inductor 16 can be suppressed to make it possible to increase the Q-factor.

FIG. 6 shows a relationship between the Q-factor of a conventional inductor using a guard ring and the Q-factor of the inductor according to the first embodiment. As is apparent from FIG. 6, in the first embodiment, the Q-factor can be increased.

The conductive region 11a and the contact 19 are formed at the central portion of the inductor 16. A magnetic field generated by the inductor 16 passes through the contact 19 and the conductive region 11a. In only the small regions, an induced electromotive force is generated. For this reason, change in the inductance can be suppressed, making it possible to set an accurate inductance.

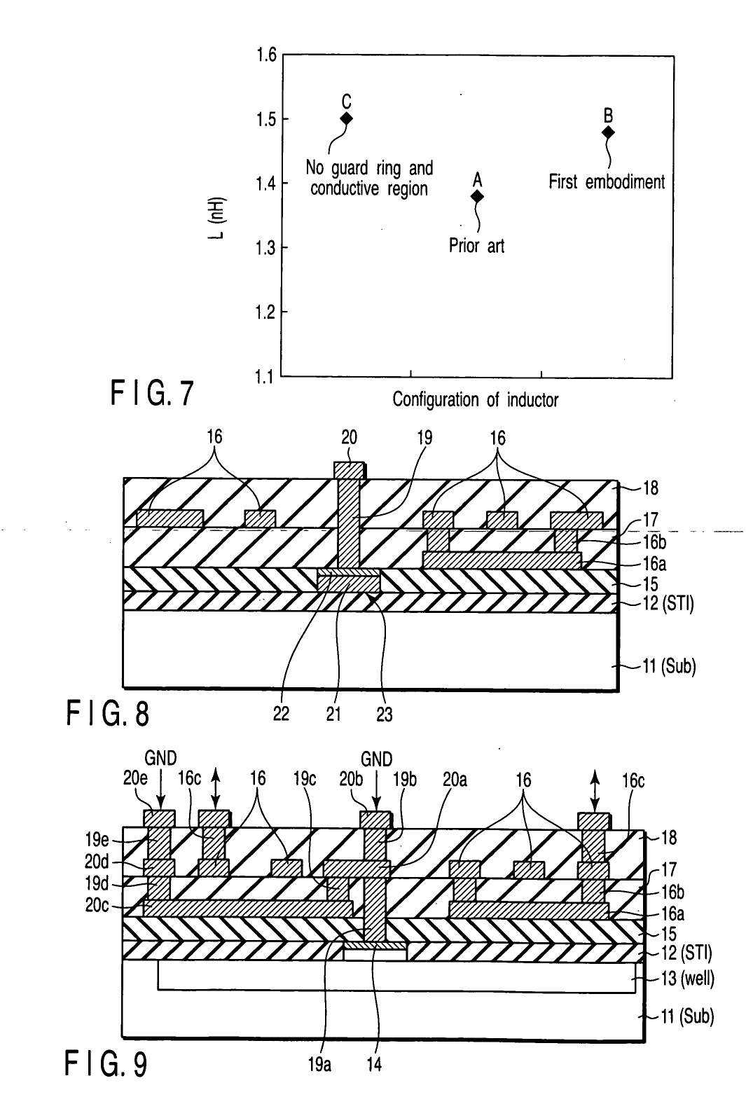

FIG. 7 shows a relationship between a configuration of an inductor and an inductance. In the configuration of the inductor described in this example, for example, the outer diameter is 211 μm, the line width is 15 μm, the number of turns is 2, and the interline space is 1.5 μm. Point A indicates the inductance obtained when a guard ring is formed around a conventional inductor, point B indicates the inductance of the inductor according to the first embodiment, and point C indicates the inductance obtained when none of a conventional guard ring, the conductive region 11a and the contact 19 according to the first embodiment are formed.

As is apparent from FIG. 7, according to the first embodiment indicated by point B, the inductance can be improved in comparison with the inductor having the conventional guard ring and indicated by point A. According to the first embodiment, the inductance is almost equal to the inductance obtained when none of the guard ring, the conductive region 11a, and the contact 19 indicated by point C are formed. For this reason, the conductive region 11a and the contact 19 slightly affect the inductance, making it possible to obtain an inductance as designed.

In the first embodiment, the element isolation region 12 has a large area. For this reason, when an insulating film is planarized by CMP, in order to avoid the influence of dishing, the element isolation region 12 may be divided into a plurality of portions to expose the substrate between the plurality of element isolation regions.

### Second embodiment

FIG. 8 shows a second embodiment of the invention. In the first embodiment, a constant potential is applied to the well region 13 formed in the substrate 11 to suppress the induced electromotive force generated in the substrate according to use change of a magnetic field generated from the inductor 16. In contrast to this, in the second embodiment, a well region corresponding to the inductor is not formed in the substrate 11.

More specifically, as shown in FIG. 8, an element isolation region 12 is formed in a surface region of the substrate 11. The element isolation region 12 does not have a region for exposing the substrate in a region in which the inductor 16 is formed, unlike in the first embodiment. On the element isolation region 12, a polysilicon layer 21 is formed in the interlayer insulating film 15 in accordance with the central portion of the spiral-shaped inductor 16. The upper surface of the polysilicon layer 21 is silicified to form a silicide layer 22. The polysilicon layer 21 and the silicide layer 22 form a conductive region 23. A contact 19 is connected to the silicide layer 22 through an interlayer insulating film 17 and an insulating film 18, and a wiring 20 is connected to the contact 19. A constant potential, for example, ground potential is applied to the conductive region 23 through the wiring 20 and the contact 19. The potential is not limited to ground potential. The other configuration is the same as that in the first embodiment.

According to the second embodiment, the conductive region 23 constituted by the polysilicon layer 21 and the silicide layer 22 is formed on the central portion of the spiral-shaped inductor 16, and, for example, ground potential is applied to the conductive region 23 through the contact 19. Therefore, magnetic flux generated by the spiral-shaped inductor 16 passes through the conductive region 23 and the contact 19, the potentials of which are held constant, and an induced electromotive force generated in the contact 19 and the conductive region 23 is grounded. For this reason, variation in the potential of the substrate can be suppressed.

Furthermore, since a guard ring larger than the inductor 16 is not necessary, the shape of the inductor 16 can be kept from being increased in size. In addition, since a large guard ring is not necessary, energy loss of the inductor 16 can be reduced to make it possible to increase the Q-factor.

### Third embodiment

FIG. 9 shows a third embodiment of the invention. The third embodiment is obtained by modifying the first embodiment. The same reference numerals as in the first embodiment denote the same parts in the third embodiment, and only different parts will be described below. In the first embodiment, the contact 19 and the wiring 20 are formed in one layer. In contrast to this, contacts and wirings are formed in a large number of layers in the third embodiment.

More specifically, in FIG. 9, a contact 19a is connected to the silicide layer 14, and a wiring 20a is connected to the contact 19a. A contact 19b and a wiring 20b are connected to the wiring 20a. Furthermore, the wiring 20a is connected to contacts 19c and 19d, and wirings 20c, 20d, and 20e for applying a potential. Both ends of the inductor 16 are also led to the surface of the insulating film 18 through the contact 16c.

According to the third embodiment, the contacts 19a and 19b and the wirings 20a and 20b are laminated on the silicide layer 14. For this reason, limitation of the arrangement of the wiring 20a for the inductor 16 can be reduced to make it possible to reliably apply a constant potential to the well region 13. Furthermore, the contacts and the wirings are laminated to make it possible to moderate the aspect ratio of the contacts, and high and long contacts can be formed. Therefore, the resistance to the magnetic field from the inductor 16 can be increased.

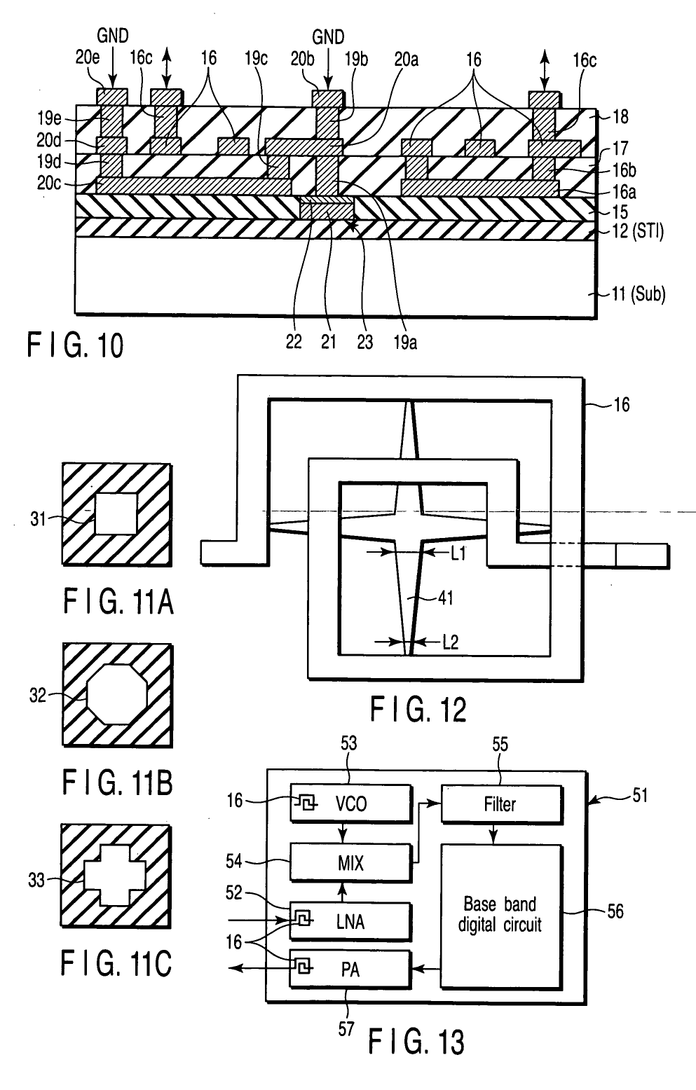

FIG. 9 shows a case in which laminated contact and wirings are applied to the first embodiment. However, the configuration is applied to not only the first embodiment but also the second embodiment as shown in FIG. 10. In this case, the number of layers of the contacts 19a and 19b and the wirings 20a and 20b is increased to make it possible to efficiently suppress the induced electromotive force due to the magnetic field generated by the inductor, and variation in potential of the substrate can be suppressed.

FIGS. 11A to 11C show the planar shapes of the conductive region 11a, the silicide layer 14, and the conductive region 23 to which the constant potential is applied. The regions preferably have shapes that exhibit resistance to an induced electromotive force generated according to the magnetic field of the inductor 16. A conductive region 31 shown in FIG. 11A is rectangular, a conductive region 32 shown in FIG. 11B is octagonal, and a conductive region 33 shown in FIG. 11C is cruciform. In FIGS. 11A, 11B, and 11c, if magnetic fluxes are generated perpendicularly to the drawings, currents are generated around the magnetic fluxes in the drawings. As a shape that exhibits a high resistance to the current, when the outer diameter of the region is not changed, the resistance increases in inverse proportion to the area of a circle inscribed on the region. When the three shapes shown in FIGS. 11A, 11B, and 11C are used, the resistances satisfy the condition given by: conductive region 31<conductive region 32<conductive region 33. The conductive region 33 shown in FIG. 11 exhibits the highest resistance. In general, a shape having a large number of acute angles exhibits a high resistance. For this reason, each of the conductive region 11a, the silicide layer 14, and the conductive region 23 preferably have the shape shown in FIG. 11C.

On the other hand, FIG. 12 shows a case in which a conductive region 41 larger than the inner diameter of the inductor 16 is formed under the inductor 16. As the configuration of the conductive region 41, any one of the configurations according to the first and second embodiments may be used. The conductive region 41 is, for example, cruciform. The width of the conductive region 41 corresponding to the outer diameter of the inductor 16 is designed to gradually decrease from a central portion L1 of the inductor 16 to an outer circumference L2. For this reason, the resistance of the conductive region 41 gradually increases toward the outer circumference of the inductor 16 in comparison with the central portion of the inductor 16.

Also with the configuration, since the diameter of the conductive region 41 is smaller than the outer diameter of the inductor 16, the shape of the inductor 16 can be prevented from increasing in size. Furthermore, the region in which an induced electromotive force is generated is smaller than that of the prior art, and the resistance set at a position in the region increases as the position becomes close to the outer circumference of the inductor 16. For this reason, the energy loss of the inductor 16 can be suppressed to make it possible to increase the Q-factor.

FIG. 13 shows an example of a system LSI to which the embodiments described above are applied. This LSI includes, for example, a high-frequency circuit applied to a mobile telephone, a wireless LAN, and the like. In a semiconductor chip 51, a low-noise amplifier (LNA) 52, a voltage-controlled oscillator (VCO) 53 serving as a local oscillator, a mixer (MIX) 54, a filter 55, a baseband digital circuit 56, and a power amplifier (PA) 57 are arranged. The LNA 52 receives a high-frequency input signal. The MIX 54 mixes an output signal from the LNA 52 and a signal from the VCO 53 to output an intermediate-frequency signal. The output signal from the MIX 54 is supplied to the baseband digital circuit 56 through the filter 55. The baseband digital circuit 56 performs desired processing on an input signal. The output signal from the baseband digital circuit 56 is amplified by the PA 57 and output.

The inductor 16 is arranged in, for example, the LNA 52, the VCO 53, or the PA 57. In particular, an inductor arranged in the VCO 53 must have an accurate inductance and requires a high Q-factor. For this reason, with configurations described in the first and second embodiments, the performance of the VCO 53 can be improved.

As shown in FIG. 12, a chip arranged in a high-frequency circuit of this type has a plurality of inductors. For this reason, each inductor is decreased in size to reduce the area occupied in the chip. Since the inductor according to each embodiment has not a guard ring larger than the outer circumference of the inductor, unlike in the prior art, the inductor can be reduced in size, and the area occupied in the chip can be advantageously reduced.

In each of the embodiments, the conductive regions 11a and 23 are arranged in the central portion inside the inner circumference of the spiral-shaped inductor. However, the position is not limited to the central portion, and the conductive regions 11a and 23 can also be formed at a position other than the central portion. Furthermore, the number of conductive regions is not limited to one, and a plurality of conductive regions can be formed.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device comprising:
a semiconductor substrate;
an element isolation region formed in a surface region of the semiconductor substrate;
a spiral-shaped inductor formed above the element isolation region; and
a conductive region which is formed inside an inner circumference of the inductor and to which a constant potential is applied.

2. The device according to claim 1, wherein the conductive region is connected to the semiconductor substrate.

3. The device according to claim 1, wherein the conductive region is formed on the element isolation region.

4. The device according to claim 1, further comprising:
a plurality of laminated wirings formed on the conductive region.

5. The device according to claim 1, wherein the conductive region has a size almost equal to that of an outer shape of the inductor, and a resistance outside the inductor is higher than a resistance at a central portion.

6. The device according to claim 2, wherein the conductive region is constituted by a part of the semiconductor substrate isolated by the element isolation region and a silicide layer formed on the part of the semiconductor substrate.

7. The device according to claim 3, wherein the conductive region is constituted by a polysilicon layer formed on the element isolation region and a silicide layer formed on the polysilicon layer.

8. The device according to claim 6, wherein a planar shape of the conductive region is one of a rectangular shape, an octagonal shape, and a cruciform shape.

9. The device according to claim 7, wherein a planar shape of the conductive region is one of a rectangular shape, an octagonal shape, and a cruciform shape.

10. The device according to claim 5, wherein the conductive region has a cruciform shape having a size almost equal to that of an outer shape of the inductor, and the conductive region has a distal end having a width smaller than that of a central portion.

11. The device according to claim 1, wherein the inductor is formed in a system LSI including a high-frequency circuit.

12. A system LSI comprising:
a semiconductor substrate; and
a circuit including a spiral-shaped inductor formed in the semiconductor substrate, the inductor comprising:
an element isolation region formed in a surface region of the semiconductor substrate;
a spiral-shaped conductive layer formed above the element isolation region; and
a conductive region formed inside which is formed inside an inner circumference of the spiral-shaped conductive layer and to which a constant potential is applied.

13. The device according to claim 12, wherein the conductive region is connected to the semiconductor substrate.

14. The device according to claim 12, wherein the conductive region is formed on the element isolation region.

15. The device according to claim 12, further comprising:
a plurality of laminated wirings formed on the conductive region.

16. The device according to claim 12, wherein the conductive region has a size almost equal to that of an outer shape of the inductor, and a resistance outside the inductor is higher than a resistance at a central portion.

17. The device according to claim 13, wherein the conductive region is constituted by a part of the semiconductor substrate isolated by the element isolation region and a silicide layer formed on the part of the semiconductor substrate.

18. The device according to claim 14, wherein the conductive region is constituted by a polysilicon layer formed on the element isolation region and a silicide layer formed on the polysilicon layer.

19. The device according to claim 17, wherein a planar shape of the conductive region is one of a rectangular shape, an octagonal shape, and a cruciform shape.

20. The device according to claim 14, wherein the conductive region has a cruciform shape having a size almost equal to that of an outer shape of the inductor, and the conductive region has a distal end having a width smaller than that of a central portion.
